(19) United States
(12) Patent Application Publication
(10) Pub. No.: US 2009/0108253 A1
(43) Pub. Date: Apr. 30, 2009

(54) Electronic component

(76) Inventors: Andreas Ullmann, Zirndorf (DE); Alexander Knobloch, Erlangen (DE); Merlin Welker, Baiersdorf (DE); Walter Fix, Nurnberg (DE)

Correspondence Address: CARELLA, BYRNE, BAIN, GILFILLAN, CECCHI,;STEWART & OLSTEIN, 5 BECKER FARM ROAD, ROSELAND, NJ, 07068, US

(21) Appl. No.: 11/989,623

(22) PCT Filed: Jul. 27, 2006
(86) PCT No.: PCT/EP2006/007442

§ 371 Date: Mar. 4, 2008

(30) Foreign Application Priority Data
Jul. 29, 2005 (DE) 10 2005 035 590.0

(51) Int. Cl. H01L 51/10

(52) U.S. Cl. 257/40; 257/E51.002

(57) ABSTRACT

The invention relates to an electronic component comprising a flexible substrate, on the surface of which is arranged a layer stack composed of thin layers, containing at least one electrical functional layer composed of an electrically conductive or semiconducting material, wherein the component comprises at least a first material, a layered second material and a layered third material and wherein, as seen perpendicular to the surface of the substrate the first material is followed by the second material and the second material is followed by the third material, wherein a first adhesion force of the second material to the first material is lower than a second adhesion force of the third material to the first material and the second material has at least one opening, via which the third material is connected to the first material in order to increase the adhesion of the second material to the first material.

The invention relates to an electronic component comprising a flexible substrate, on the surface of which is arranged a layer stack composed of thin layers, containing at least one electrical functional layer composed of an electrically conductive or semiconducting material, wherein the component comprises at least a first material, a layered second material and a layered third material and wherein, as seen perpendicular to the surface of the substrate the first material is followed by the second material and the second material is followed by the third material.

Electronic components of this type are known from DE 103 38 277 A1 which describes an organic capacitor having a voltage-controlled capacitance. The organic capacitor has a flexible substrate on which are arranged in sequence a first electrode, an organic semiconductor layer, an insulator layer and a second electrode. In this case, the electrodes can be produced from organic, metallic or other electrically conductive materials. The insulator layer is formed from either an organic or an inorganic electrically insulating material. The voltage control of the capacitance is brought about firstly by the semiconductor layer and additionally by a suitable patterning of the first electrode.

Furthermore, WO 2004/047144 discloses an organic electronic component, in particular a field effect transistor (OFET). An OFET is described which has a substrate and thereon, in sequence source/drain electrodes, a patterned organic semiconductor layer, an insulating functional layer and a gate electrode. In the mass production of electronic components with organic functional layers, thin organic polymeric and metallic layers are usually applied to a flexible substrate. For this purpose, the substrate passes through, for example, vapor deposition or sputtering installations, printing, rewinding, cutting or winding machines or automatic placement machines, wherein the flexible substrate is guided by way of various roll systems and is deformed in the process.

The resultant mechanical stress of the layers or layer stack applied on the substrate can lead, given a lack of adhesion between the substrate and the adjoining layer(s) or between layers adjoining one another in the layer stack, to partial or complete detachment of one or more layers which can lead to an impairment of the functionality of the component or of partial regions of the component through to the total failure thereof. Therefore, use is often made of adhesion promoter layers that are intended to improve the adhesion of the different materials to one another. However, in the area of electronics, in particular in the area of polymer electronics, adhesion promoter layers of this type have proved often to be disturbing since they can impair the function of an electronic component.

Therefore, it is an object of the invention to prevent the complete or partial detachment of one or more layers in the production of an electronic component constructed in layers, in particular of an organic component containing at least one electrical functional layer composed of an electrically conductive or semiconducting material, without the use of adhesion promoter layers.

The object is achieved for an electronic component, in particular an organic electronic component, comprising a flexible substrate, on the surface of which is arranged a layer stack composed of thin layers, containing at least one electrical functional layer composed of an electrically conductive or semiconducting material, wherein the component comprises at least a first material, a layered second material and a layered third material and wherein, as seen perpendicular to the surface of the substrate the first material is followed by the second material and the second material is followed by the third material by virtue of the fact that a first adhesion force of the second material to the first material is lower than a second adhesion force of the third material to the first material and that the second material has at least one opening, via which the third material is connected to the first material in order to increase the adhesion of the second material to the first material.

Through such a configuration of the electronic component, the layered second material gains in flexibility and is additionally anchored or attached to the first material by means of the third material in the region of the at least one opening. Since the third material adheres to the first material better than the second material, the good adhesion of the third material to the first material is utilized to fix the second material in the region of the openings in point-type or linear fashion. This results in a higher flexibility of the component and a better composite assemblage of the individual materials in the electronic component.

The risk of a deformation of the flexible substrate and layers applied thereon in the production of the electronic component leading to a complete or region-by-region detachment of layers in the region of the second material is minimized.

Furthermore, the configuration of the electronic component according to the invention enables the layers for the construction thereof, in particular the layer composed of the second material, to be able to be formed very much thinner than hitherto. This is because particularly thin layers hitherto proved to be desired breaking points in layer stacks at which the structural integrity was particularly jeopardized. The possibility now opened up for using particularly thin layers has an expedient effect in particular on the production costs for an electronic component.

In this case, it has proved worthwhile if the first adhesion force is at least 50%, in particular at least 75%, lower than the second adhesion force. Such a difference between the first and second adhesion force makes it appear to be particularly promising to utilize the better adhesion of the third material to the first material in order to anchor the second material to the first material.

It has proved worthwhile if the first material forms the surface of the substrate, the second material is provided by a first layer arranged on the surface of the substrate, and the third material is provided by a second layer arranged on the surface of the first layer.

It is equally advantageous, however, if the first, the second and the third material are provided by three thin layers of the layer stack. In this case, these can directly adjoin the substrate or be arranged in a manner spaced apart from one another.

It goes without saying that the invention can also relate to a plurality of regions of the electronic component simultaneously. Thus, by way of example, a layered third material can be covered on both sides with a layered second material, wherein the third material anchors the second material on one side at a substrate and anchors it on the other side at a further layer composed of a first material. Diverse embodiments are obvious in this case to the person skilled in the art without departing from the subject matter of the invention.

In particular, the thin layers of the layer stack in each case have a layer thickness within the range of 1 nm to 10 μm, preferably within the range of 1 nm to 1 μm. For semiconducting layers, a layer thickness within the range of 1 nm to 300 nm is preferred in this case. Electrically insulating layers or protective layers are preferably formed with a layer thickness within the range of 5 nm to 1 μm while electrically conductive layers are preferably formed with a layer thickness within the range of 1 nm to 100 nm. Such layer thicknesses enable an optimum anchoring of the second material at the first material in the region of the at least one opening.

Furthermore, the flexible substrate can be formed in multilayered fashion. Thus, substrates composed of different material layers which usually are sufficiently fixedly connected to one another with regard to the processing process are used, inter alia, wherein only that surface of the substrate which adjoins the layer stack is of interest with regard to the adhesion of the layers applied thereto. Thus, the substrate can have, for example, paper, plastic, metal, fabric layers or inorganic layers, depending on the desired properties. Preferably, however, the substrate is provided by a film composed of PET or PVP or composed of—if appropriate plastic-coated—paper.

The flexibility of the electronic component makes the latter particularly durable, in particular totally insensitive to impact loads. In contrast to components constructed on rigid substrates, those with flexible substrates can be used in applications in which the electronic component is intended to nestle against objects having an irregular contour, for example, packages. These increasingly tend to be provided for devices having irregularly formed contours, such as mobile phones or electronic cameras.

It is particularly preferred if the second material delimits the at least one opening at at least 50% of the opening periphery, in particular at 100% of the opening periphery. Thus, it is possible to arrange an opening in the layered second material for example in the edge region or within the layer. Openings in the region of the layer corner or layer edge lead to a lengthening of the periphery of the layer composed of second material and thus to an improved anchoring thereof by means of the layered third material at the first material. Openings in the layer composed of second material which are arranged in a manner remote from the edge, that is to say surrounded by second material on all sides as seen perpendicular to the substrate, are particularly preferred in the case of layers composed of second material which are formed at least in regions with the width such that there is the risk of an areal detachment/bulging in the central region. An opening having 100% of its periphery delimited by second material reduces the width of the layer composed of second material in this region and enables a connection between the third material and the first material through the layer composed of second material. This increases the flexibility and adhesion between the second and the first material and reduces the risk of a detachment in the central region of the layer composed of second material. An arrangement of openings in the edge region and in the central region of the layer composed of second material is particularly preferred.

It has furthermore proved worthwhile if the at least one opening has at its maximum cross section, as seen perpendicular to the surface of the substrate, a width within the range of 0.5 to 200 μm, in particular within the range of 0.5 to 2.5 μm. Openings configured in this way enable a sufficient contact between the layered third material and the first material. Openings having smaller diameters are more likely to impede the third material from coming into contact with the first material, such that sufficient anchoring does not occur, while larger opening diameters can significantly impair the functionality of the layer composed of second material.

Overall, it has proved worthwhile if approximately 5 to 50%, in particular 5 to 10% of the area of the second material is occupied by openings. In particular, not more than 50% of a dimension of the second material that is critical for the electrical values of the component which should be interrupted by openings, in order not to impair the functionality of the component.

Generally it is possible to form a wide variety of opening cross-sections, for example, in circular, elliptical, square, rectangular, triangular, star-shaped form or free form and a combination of those forms.

Preferably, the second material has a layer thickness within the range of 1 to 200 nm. Layered second materials having layer thicknesses of this type enable a sufficient contact between the layered third material and the first material. Thicker layers composed of second material impede the anchoring of the third material at the first material such that the second material is not anchored sufficiently.

Furthermore it has proved to be favorable if a layer thickness of the third material is at least 10% of the layer thickness of the second material. This ensures that the layer composed of third material forms a closed layer and is not interrupted in the region of the at least one opening. Thinner layers composed of third material impede the anchoring of the third material at the first material such that the second material is not anchored sufficiently.

In particular it is preferred if the layered second material, as seen perpendicular to the surface of the substrate, is provided with openings approximately up to 50% of the total area. In this case, a suitable setting of the width of the webs composed of second material which remain between the openings and at the edge is brought about by means of a uniform arrangement of openings, thereby preventing the detachment and, if appropriate, bulging of wide layers composed of second material in their central region as already mentioned above.

In this case, it has proved worthwhile if the second material has, as seen perpendicular to the surface of the substrate, at every location a width that deviates by less than approximately 25% from the width of the second material in the rest of the regions. In this case the more uniform the web widths of the layer composed of second material are formed, the more uniform, too, is the attained improvement in the adhesion of the second material to the first material.

Preferably the second material is electrically conductive, and is formed in particular from a metal, a conductive polymer, a conductive adhesive, a conductive substance having conductive inorganic particles in a polymer matrix or from a paste/ink containing electrically conductive particles. In this case, by way of example, gold, silver, titanium, copper or alloys thereof are appropriate as metal. Polyaniline or polyethylenedioxythiophene (PeDOT), inter alia, have proved worthwhile as conductive polymers while pastes/ink having silver or graphite/carbon black particles are often used as pastes/inks containing electrically conductive particles.

In this case, it is particularly preferred if the second material functions as a first electrode. In this case, a first electrode should also be understood to mean electrode pairs, for example, the source and drain electrodes of a p-conducting field effect transistor that are arranged at the same level on the substrate.

In this case, it is particularly preferred if the component furthermore has a second electrode, which likewise has openings for increasing its flexibility. In this case, the openings in the second electrode are formed analogously to the openings in the first electrode, which is tantamount to meaning that here the number, arrangement and the opening cross-section are formed as if an opening in the layered second material were involved.

In this case, the openings in the second electrode can be formed congruently with the openings in the first electrode, in particular in the case of identical area dimensions of first and second electrode, or deviate in terms of type, number and position, in particular in the case of deviating area dimensions of first and second electrode.

Furthermore, it is possible for the second material to be formed in multilayered fashion, in particular from a plurality of metal layers and/or a plurality of polymer layers and/or a plurality of paste/ink layers or the like. The adhesion force of the individual layer composed of second material adjoining the first material or the adhesion force of the individual layer composed of third material adjoining the first material is crucial in this case.

It is preferred if the third material forms the electrical functional layer composed of electrically conductive or semiconducting material. The semi-conducting electrical functional layer can preferably be formed by means of printable, soluble inorganic semiconductors or polymers, where the term polymer here expressly includes polymeric material and/or oligomeric material and/or material composed of small molecules, and/or material composed of nanoparticles. Nanoparticles comprise organometallic semiconductor-organic compounds containing for example zinc oxide as non-organic constituent. The polymer can be a hybrid material, for example, in order to form an n-conducting polymeric semiconductor. Silicones, for example, are also included. Furthermore, the term is not intended to be restrictive with regard to the molecular size, but rather, as explained further above, to include “small molecules” or “nanoparticles”. It may be provided that the semiconductor layers are formed with different organic materials.

The semiconductor layer can be formed as p-type conductor or as n-type conductor. The current conduction in a p-type conductor is effected almost exclusively by defect electrons, and the current conduction in an n-type conductor is effected almost exclusively by electrons. The respectively prevailing charge carriers present are referred to as majority carriers. Even though the p-type doping is typical of organic semiconductors, it is nevertheless possible to form the material with n-type doping. Pentacene, polyalkylthiophene, etc. can be provided as p-conducting semiconductors and e.g. soluble fullerene derivatives can be provided as n-conducting semiconductors.

Furthermore, it has proved to be advantageous if the third material forms the electrical functional layer composed of electrically conductive or semiconducting material, wherein traditional semiconductors (crystalline silicon or germanium) and typical metallic conductors are used.

Preferably, the layered second material has at least two openings wherein the at least two openings have the same cross section, as seen perpendicular to the surface of the substrate. This configuration of the openings is appropriate in particular when the layer composed of second material has a simple geometrical form, for example is formed in rectangular, square, round or similar fashion.

It is likewise possible however, for the second material to have at least two openings wherein the at least two openings have at least one different cross section, as seen perpendicular to the surface of the substrate. Such a configuration of the openings proves to be advantageous in particular when the layer composed of second material has a more complex geometrical form with angled portions, for example is formed in T-shaped or star-shaped fashion.

It has proved to be advantageous if the electronic component is formed as an organic semiconductor component, in particular a field effect transistor (OFET), as an organic diode, as an organic capacitor having a voltage-controlled capacitance, as an organic resistor or as an organic electrical conduction arrangement.

An organic field effect transistor (OFET) is a field effect transistor having at least three electrodes, a semiconductor layer and an insulating layer. The OFET is arranged on a carrier substrate. A layer composed of an organic semiconducting material forms a conductive channel, the end sections of which are formed by a source electrode and a drain electrode. The conductive channel is covered with an insulation layer, on which a gate electrode is arranged. The conductivity of the channel can be altered by applying a gate-source voltage U_{GS} between gate electrode and source electrode. The charge carriers are densified by the formation of an electric field in the insulation layer if a gate-source voltage U_{GS} of suitable polarity is applied, i.e. a negative voltage in the case of p-type conductors or a positive voltage in the case of n-type conductors. Consequently, the electrical resistance between the drain electrode and the source electrode decreases. Upon application of a drain-source voltage U_{DS}, a larger current flow between the source electrode and the drain electrode can then form than in the case of an open gate electrode. A field effect transistor is therefore a controlled resistor.

In particular, it is preferred for the electronic component if the electrical functional layer composed of an electrically conductive or semiconducting material is formed by means of a liquid, in particular by a printing method. In this case, the term liquid encompasses for example suspensions, emulsions, other dispersions or else solutions. In this case, the printing behavior of the liquid is determined by parameters such as viscosity, concentration, boiling point and surface tension. Thus, a variation of the thickness of the electrical functional layer formed by printing can be achieved either by increasing the concentration of organic material, for example, polymer in the liquid or by increasing the application quantity in a printing operation or by increasing the number of liquid applications with intermediate drying. In this case, intaglio printing, relief printing, screen printing, flexographic or pad printing or stencil printing or the like can be used as printing methods. Methods that can be equated with a printing method, such as blade coating, are also possible.

Furthermore, it is preferred for the electronic component if the electrical functional layer composed of an electrically conductive or semiconducting material is formed by deposition by means of a gas phase, in particular by vapor deposition or sputtering.

It has proved worthwhile for the electronic component if the electrical functional layer composed of an electrically conductive or semiconducting material is patterned by means of a laser or photolithography.

Preferably, the electrical functional layer composed of an electrically conductive or semiconducting material is formed in a continuous production method. Roll-to-roll methods are particularly preferred here.

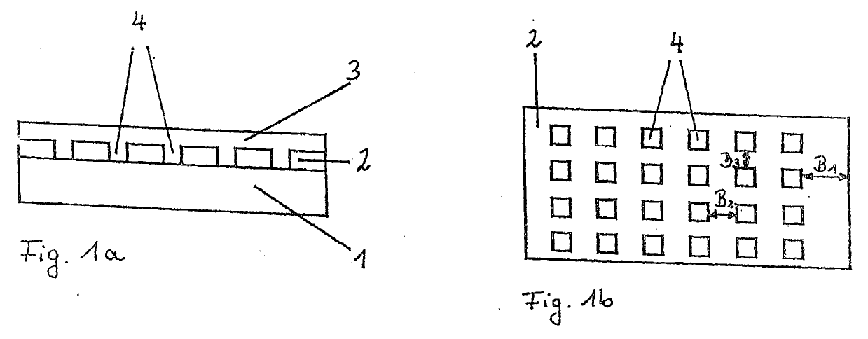

FIGS. 1a to 5c are intended to elucidate the invention by way of example. Thus:

FIG. 1a shows a cross section through a substrate with two layers arranged thereon,

FIG. 1b shows a plan view of the layer 2 from FIG. 1a,

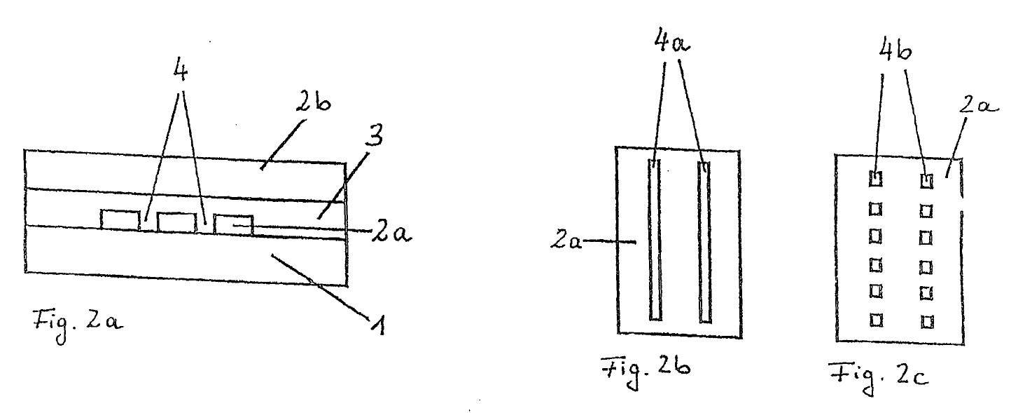

FIG. 2a shows a cross section through a substrate with three layers arranged thereon,

FIGS. 2b and 2c in each case show a plan view of one possible variant of the layer 2 from FIG. 2a,

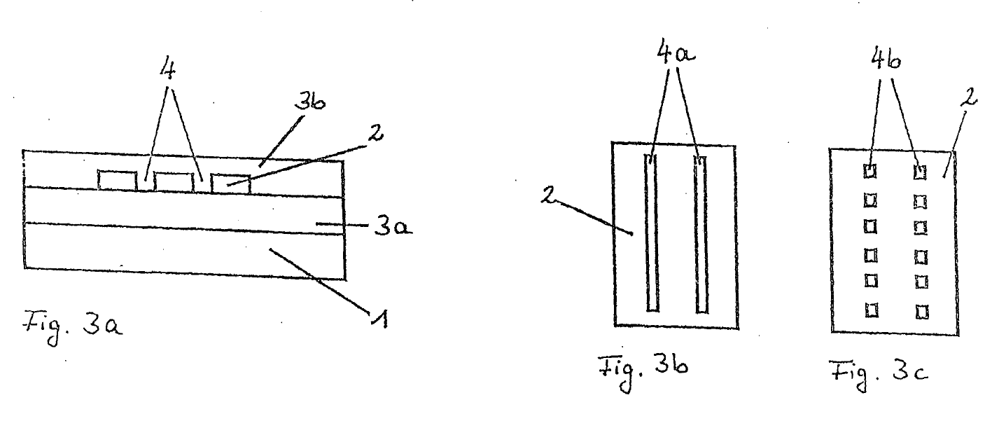

FIG. 3a shows a cross section through a further substrate with three layers arranged thereon,

FIGS. 3b and 3c in each case show a plan view of one possible variant of the layer 2 from FIG. 3a,

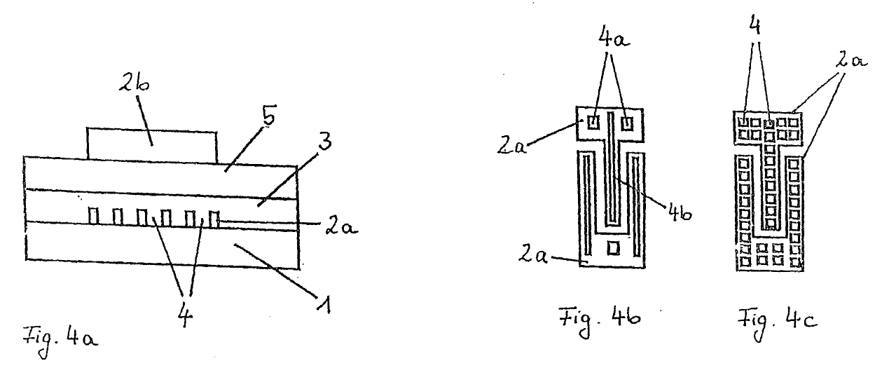

FIG. 4a shows a cross section through an OFET,

FIGS. 4b and 4c in each case show a plan view of one possible variant of the layer 2a from FIG. 4a,

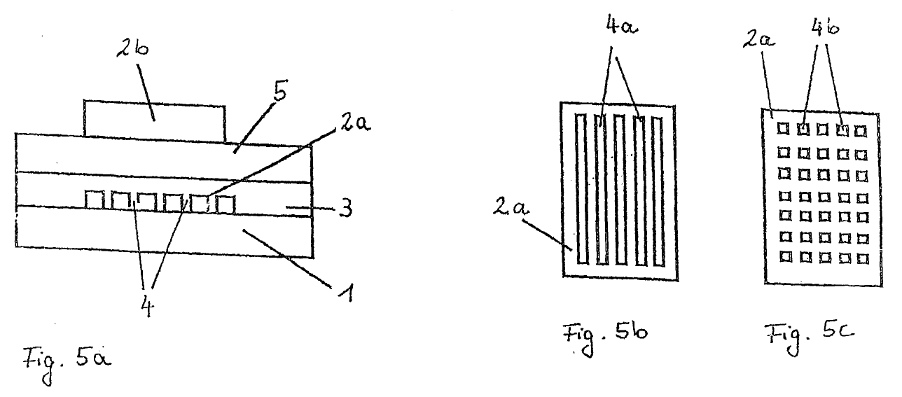

FIG. 5a shows a cross section through a capacitor having a voltage-controlled capacitance and

FIGS. 5b and 5c in each case show a plan view of one possible variant of the layer 2a from FIG. 5a.

FIG. 1a shows a cross section through a flexible substrate 1 in the form of a plastic film composed of a first material, here composed of PET. A first layer composed of a second material 2 having a layer thickness of 10 nm is arranged on the substrate 1, wherein silver applied by sputtering was used as second material 2. The first layer composed of the second material 2 has openings 4 (also see FIG. 1b). A second layer composed of a third material 3 is arranged above the first layer composed of the second material 2, wherein the second layer composed of the third material 3 has a layer thickness of 20 nm and is in contact with the substrate 1 composed of the first material through the openings 4. In order to form the second layer composed of the third material 3, in this case a liquid containing poly-3-alkythiophene was printed on and dried. In this case a second adhesion force of the third material 2 to the first material, which is provided by the surface of the substrate 1, is higher than a first adhesion force of the second material 2 to the first material.

FIG. 1b shows a plan view of the first layer composed of the second material 2 from FIG. 1a. It can be discerned in this case that the openings 4 in the second material 2 are square openings having an identical opening cross-section. The side length of the openings is 10 μm. The quantity of openings 4, and also their number and arrangement, are chosen such that less than 50% of the total area of the first layer composed of the second material 2 is cut out. The width (see for example the widths B₁, B₂ and B₃ in FIG. 1b) of the second material 2 which remains as seen perpendicular to the substrate is less than 30 μm. This ensures a reliable and uniform fixing of the second material 2 by means of the second layer composed of the third material 3 to the first material or the substrate surface.

FIG. 2a shows a cross section through a flexible substrate 1 composed of PET as first material, on which a first layer composed of a second material 2a is arranged. The layer composed of the second material 2a has been formed from silver conductive paste with a layer thickness of 15 nm and has openings 4. There is arranged on the layer composed of the second material 2a a second layer composed of a third material 3, which has a layer thickness of 35 nm and is in direct contact with the surface of the substrate 1 or with the first material through the openings 4. A planar electrode 2b formed by means of silver conductive paste is arranged on the second layer composed of the third material 3. In order to increase the flexibility of the electrode 2b, the latter is preferably likewise provided with openings in accordance with the first layer composed of the second material 2a (not illustrated here). The third material 3 is formed from the organic semiconducting material pentacene, wherein the adhesion force of the third material 3 to the substrate 1 is higher than the adhesion force of the second material to the substrate 1.

FIGS. 2b and 2c in each case show a plan view of one possible variant of the first layer from FIG. 2a, wherein FIG. 2b shows two rectangular openings 4a of identical size and FIG. 2c shows a plurality of square openings 4b of identical size which can be used as openings 4 in accordance with FIG. 2a. In this case, the opening cross-sections of the openings 4a, 4b are chosen to be so small in relation to the area extent of the first layer that the function of the first layer is not impaired. In this case, the ratio between the sum of the opening cross-sections of all the openings to the area of the first layer preferably lies within the range of 1:20 to 1:1.

FIG. 3a shows a cross section through a flexible substrate 1 composed of paper, on which a layer composed of a first material 3a is arranged. In this case, the first material 3a is formed from the organic semiconductor poly-3-alkylthiophene with a layer thickness of 15 nm. A layer composed of a second material 2 and having openings 4 is formed on the layer composed of the first material 3a. The second material 2 is formed from vapor-deposited copper with a layer thickness of 10 nm. A further layer composed of a third material 3b having a layer thickness of 15 nm is arranged on the layer composed of the second material 2, wherein the third material 3b is chosen to be identical to the first material 3a. This results in a higher adhesion force between the layers composed of the third material 3b and the first material 3a than between the layer composed of the second material 2 and the layer composed of the first material 3a.

FIGS. 3b and 3c in each case show a plan view of one possible variant of the layer 2 from FIG. 3a, wherein FIG. 3b shows two rectangular openings 4a of identical size and FIG. 3c shows a plurality of square openings 4b of identical size which can be used as openings 4 in accordance with FIG. 3a.

FIG. 4a shows a cross section through an OFET with a flexible substrate 1 composed of PVP (=first material), a first layer composed of a second material 2a, here vapor-deposited gold with a layer thickness of 12 nm, wherein the first layer provides the source/drain electrodes of the OFET, and also a second layer composed of a third material 3, which is organic-semiconducting, here formed from poly-3-alkylthiophene. Situated on the second layer, composed of the third material 3, which has a layer thickness of 23 nm, there is an organic electrically insulating layer 5 which in turn carries a gate electrode 2b composed of vapor-deposited gold. The first layer composed of the second material 2a has openings 4 through which the second layer composed of the third material 3 is in contact with the first material or with the surface of the substrate 1. This results in a good adhesion of the first layer composed of the second material 2 to the first material. In order to increase the flexibility and adhesion of the electrode 2b, the latter is preferably likewise provided with openings similar to those in the first layer composed of the second material 2a (not illustrated here).

FIGS. 4b and 4c in each case show a plan view of one possible variant of the layer 2a from FIG. 4a. In this case, openings 4a, 4b having different opening cross-sections are provided in FIG. 4b, while only openings 4 having an identical opening cross-section are arranged in FIG. 4c.

FIG. 5a shows a cross section through a capacitor having a voltage-controlled capacitance, which has a substrate 1 composed of a first material. The first material is formed from PET film. A first layer composed of a second material 2a is arranged on the substrate 1. The second material 2a is formed from PeDOT with a layer thickness of 1 nm and has openings 4. There is arranged on the layer composed of the second material 2a a second layer composed of a third material 3, which is formed from the organic semiconductor poly-3-alkylthiophene. The second layer composed of a third material 3 is connected to the substrate 1 via the openings 4 in the first layer and thereby reliably fixes the first layer to the substrate 1. An electrically insulating layer 5 composed of polyhydroxystyrene (PHS) is arranged on the second layer. An electrically conductive layer 2b, which functions as an electrode and is formed from PeDOT, is arranged on the layer 5. In order to increase the flexibility and thus the adhesion of the electrode 2b, the latter is preferably likewise provided with openings like those in the first layer composed of the second material (not illustrated here).

FIGS. 5b and 5c in each case show a plan view of one possible variant of the layer composed of the second material 2a from FIG. 5a. In this case, openings 4a having a rectangular opening cross-section are provided in FIG. 5b, while openings 4b having a square opening cross-section are arranged in the layer composed of the second material 2a in FIG. 5c in order to improve the flexibility of the first layer and the adhesion thereof to the substrate 1.

1. An electronic component comprising:
a flexible substrate having a surface; and
a layered stack on the substrate surface comprising a plurality of relatively thin layers, the stack containing at least one organic electrical functional layer composed of an electrically conductive or semiconducting material;
wherein the component comprises at least a layered first material, a layered second material and a layered third material; and
wherein, as seen perpendicular to the surface of the substrate, the first material is followed by the second material and the second material is followed by the third material; and
wherein the layered materials exhibit a first adhesion force of the second material to the first material is lower than a second adhesion force of the third material to the first material; and
wherein the second material has at least one opening, through which the third material is connected to the first material at the higher adhesion force to thereby increase the adhesion forces of the second material to the first material.

2. The electronic component as claimed in claim 1,
wherein the first adhesion force is at least 50% lower than the second adhesion force.

3. The electronic component as claimed in claim 1 wherein the first material forms the surface of the substrate, the second material forms a first layer on the substrate surface, and the third material forms a second layer on a surface of the first layer.

4. The electronic component as claimed in claim 1 wherein the first, the second and the third materials form three layers of the layered stack.

5. The electronic component as claimed in claim 1 wherein each of the stack layers have a layer thickness within the range of 1 nm to 10 μm.

6. The electronic component as claimed in claim 1 wherein the flexible substrate is a film of PET or PVP.

7. The electronic component as claimed in claim 1 wherein the flexible substrate is multilayered.

8. The electronic component as claimed in claim 1 wherein the layered second material delimits the at least one opening at at least 50% of the opening periphery.

9. The electronic component as claimed in claim 8, wherein the at least one opening has a periphery, and the layered second material delimits the at least one opening at 100% of the at least one opening periphery.

10. The electronic component as claimed in claim 8, wherein the layered second material has a periphery and an edge region, the at least one opening being in the edge region of the layered second material for lengthening the periphery of the layered second material.

11. The electronic component as claimed in claim 1 further having at least one further opening is arranged in the edge region of the layered second material.

12. The electronic component as claimed in claim 1 wherein the at least one opening has at its maximum cross section, as seen perpendicular to the surface of the substrate, a width within the range of 0.5 to 200 μm.

13. The electronic component as claimed in claim 1 wherein the second material has a layer thickness within the range of 1 to 200 nm.

14. The electronic component as claimed in claim 1 wherein the third material has a layer thickness which is at least 10% of the layer thickness of the second material.

15. The electronic component as claimed in claim 1 wherein at least 5 to 10%, of a total area of the second material in the plane of the second material layer is occupied by openings.

16. The electronic component as claimed in claim 1 wherein the second material has, as seen perpendicular to the surface of the substrate, at every location a width that deviates by less than 25% from the width of the second material in any width direction of the second material.

17. The electronic component as claimed in claim 1 wherein the second material is electrically conductive, and is formed from at least one of a metal, a conductive polymer, a conductive adhesive, a conductive substance having conductive inorganic particles in a polymer matrix or from a paste/ink containing electrically conductive particles.

18. The electronic component as claimed in claim 17, wherein the second material functions as a first electrode in the electronic component.

19. The electronic component as claimed in claim 18, wherein the component includes a second electrode having a plurality of openings for increasing its flexibility.

20. The electronic component as claimed in claim 1 wherein as seen perpendicular to the surface of the substrate, the layered third material is followed by a further layered second material, in that the further second material is followed by a further additional layer, wherein the further second material has at least one opening through which the third material is connected to the further additional layer to increase the adhesion of the further second material to the further additional layer.

21. The electronic component as claimed in claim 1 wherein the second material is multilayered formed from a plurality of layers each layer comprising at least one of a metal, a polymer or a paste/ink.

22. The electronic component as claimed in claim 1 wherein the third material forms the organic electrical functional layer composed of electrically conductive or semiconducting material.

23. The electronic component as claimed in claim 1 wherein the second material has at least two openings and wherein the at least two openings have the same cross section, as seen perpendicular to the surface of the substrate.

24. The electronic component as claimed in claim 1 wherein the second material has at least two openings and wherein the at least two openings have at least one different cross section, as seen perpendicular to the surface of the substrate.

25. The electronic component as claimed in claim 1 wherein the stacked layers of the electronic component are arranged to comprise one of an organic semiconductor field effect transistor (OFET), an organic diode, an organic capacitor having a voltage-controlled capacitance, as an organic resistor or an organic electrical conduction arrangement.

26-29. (canceled)
